(19) United States
(12) Patent Application Publication
(10) Pub. No.: US 2023/0050002 A1
(43) Pub. Date: Feb. 16, 2023

(54) INTEGRATED CIRCUIT INTERCONNECT TECHNIQUES

(71) Applicant: Cisco Technology, Inc., San Jose, CA (US)

(72) Inventors: D. Brice ACHKIR, Livermore, CA (US); Mark C. NOWELL, Ottawa (CA); Upendranadh R. KARETI, Union City, CA (US)

(21) Appl. No.: 17/445,054

(22) Filed: Aug. 13, 2021

(51) Int. Cl. H01L 23/538; H01L 23/498; H01L 23/00; H01L 23/12; H01L 23/50; H01L 51/50

(52) U.S. Cl. CPC H01L 23/5384; H01L 23/49816; H01L 24/14; H01L 23/5386; H01L 23/12; H01L 23/50; H01L 51/50

(57) ABSTRACT

Embodiments presented in this disclosure generally relate to techniques for interconnecting integrated circuits. More specifically, embodiments disclosed herein provide a back mounted interposer (BMI) to facilitate interconnecting of integrated circuits. One example apparatus includes an integrated circuit, an interposer, and a circuit board, at least a portion of the circuit board being disposed between the integrated circuit and the interposer, where the circuit board is configured to provide electrical connection between the interposer and the integrated circuit via connection elements on a first surface of the interposer. The apparatus also includes an interface on a second surface of the interposer, the interface being configured to provide signals from the integrated circuit to an electrical component.

### TECHNICAL FIELD

Embodiments presented in this disclosure generally relate to techniques for implementing integrated circuit interconnection. More specifically, embodiments disclosed herein provide a back mounted interposer (BMI) to facilitate interconnection for an integrated circuit.

### BACKGROUND

With next generation high speed application-specific integrated circuit (ASIC) serializer/deserializer (SERDES) interfaces, there are many system implementation challenges. For example, the high-speed channel loss budgets from the ASIC input/output (IO) to a pluggable module interface or to a fabric IO are challenging to meet using trace-based printed circuit boards (PCBs). Even options with ultra-low loss materials or techniques have high cost with continued challenges to achieve performance specifications. High-speed copper cables can be used to reduce the channel's loss budget but there are: size, airflow limitations and placement issues with connectors near the ASICs.

Implementing in-package copper (IPC) in a way that is compatible with in-package optics (IPO) or co-packaged optics (CPO) is difficult. CPO is an approach to shorten electrical channels between the ASIC and the optics but does not always provide the user with flexibility to use pluggable optical or copper modules. CPO has its own set of implementation challenges as well, one of which is the need for large size substrates that are challenging to manufacture and are expensive.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIG. 1 is a side view of an electrical device having an integrated circuit (IC), package substrate, circuit board, and back mounted interposer (BMI), in accordance with an embodiment of the present disclosure.

FIG. 2 is a bottom view of a BMI having various interfaces coupled to cables, in accordance with an embodiment of the present disclosure.

FIG. 3A illustrates cables soldered to solder pads on a BMI, in accordance with an embodiment of the present disclosure.

FIG. 3B illustrates an interface on a BMI implemented using a gold pad array facilitating connection to a socket connector and cable stack, in accordance with an embodiment of the present disclosure.

FIGS. 4A and 4B illustrate components coupled to a BMI, in accordance with an embodiment of the present disclosure.

FIG. 5 illustrates multiple BMIs coupled to a circuit board, in accordance with an embodiment of the present disclosure.

FIG. 6 is a flow diagram illustrating example operations for signal communication using a BMI, in accordance with an embodiment of the present disclosure.

FIG. 7 is a flow diagram illustrating example operations for fabrication, in accordance with an embodiment of the present disclosure.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

One embodiment presented in this disclosure provides an apparatus. The apparatus generally includes: an integrated circuit; an interposer; a circuit board, at least a portion of the circuit board being disposed between the integrated circuit and the interposer, wherein the circuit board is configured to provide electrical connection between the interposer and the integrated circuit via a connection element on a first surface of the interposer; and an interface on a second surface of the interposer, the interface being configured to provide signals from the integrated circuit to an electrical component.

One embodiment presented in this disclosure provides a method. The method generally includes: generating, via an integrated circuit, a signal to be communicated with an electrical component; providing the signal to an interposer through a circuit board configured to provide electrical connection between the interposer and the integrated circuit via connection elements on a first surface of the interposer, wherein at least a portion of the circuit board is disposed between the integrated circuit and the interposer; and communicating, via an interface on a second surface of the interposer, the signal to the electrical component.

One embodiment presented in this disclosure provides a method. The method generally includes: disposing an integrated circuit on a circuit board; and disposing an interposer on the circuit board such that at least a portion of the circuit board is disposed between the integrated circuit and the interposer, wherein: the circuit board is configured to provide electrical connection between the interposer and the integrated circuit via connection elements on a first surface of the interposer; and an interface is formed on a second surface of the interposer, the interface being configured to provide signals from the integrated circuit to an electrical component.

### Example Embodiments

There are currently industry efforts to develop high-speed connectors on a printed circuit board (PCB) in order for a high-speed interfaces to be implemented in close proximity to an integrated circuit (IC) on the PCB. However, current solutions for implementing high-speed interfaces involve PCB routing and IC (e.g., application specific IC (ASIC)) escape (e.g., routing of traces out from below to ASIC) which add loss and transitions within the channel.

Certain embodiments of the present disclosure are directed to an IC interconnect approach that addresses these challenges and enables interconnecting of ICs. Certain embodiments allow for decoupling of high-speed interconnects from the IC by implementing the high-speed interconnects below a PCB on which the IC is disposed, while maintaining current IC design workflows, and enabling high-speed interconnects with a flexible mounting approach. For example, an interposer may be mounted below a PCB, where an IC is disposed above the PCB. The interposer may be referred to herein as a back mounted interposer (BMI). In other words, the interposer may be mounted on the reverse side (e.g., back side) of the PCB from the ASIC. The high-speed interfaces can be directly connected between the IC substrate and the interposer using via structures in the PCB.

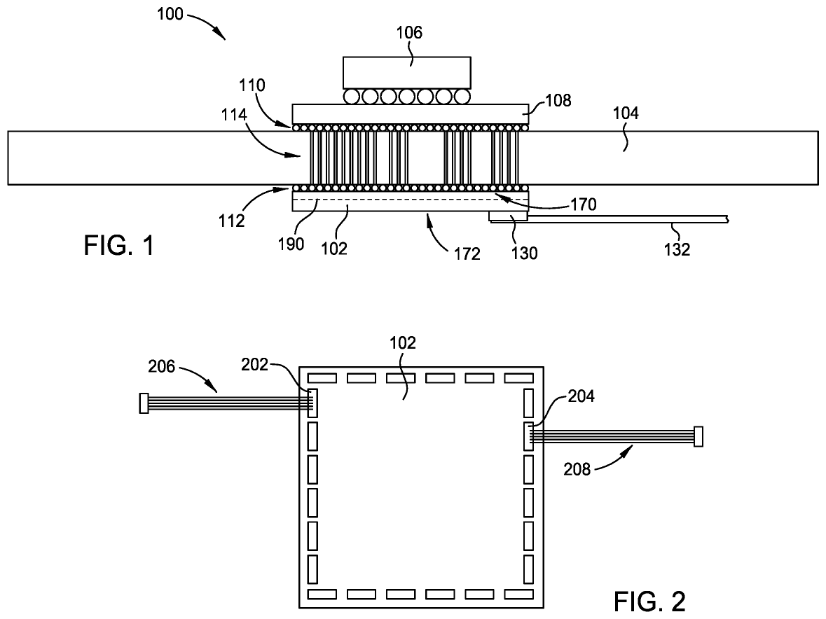

FIG. 1 is a side view of an electrical device 100 having an IC, package substrate (e.g., an ASIC package substrate), PCB, and BMI, in accordance with an embodiment of the present disclosure. As shown, an interposer 102 (e.g., BMI) may be coupled below a circuit board 104 (e.g., a PCB). Moreover, an IC 106 (e.g., a die) is coupled above the circuit board 104 such that a portion of the circuit board 104 is between the IC 106 and the interposer 102. In some embodiments, the IC 106 may be coupled to the circuit board 104 through a package substrate 108. The package substrate 108 is electrically and physically coupled to the circuit board 104 using a ball grid array (BGA) 110, in some implementations. Similarly, the interposer 102 is electrically and physically coupled to the circuit board 104 using a BGA 112, as shown. While the example provided in FIG. 1 uses BGAs for electrically coupling to facilitate understanding, any suitable technique for providing electrically connection may be used.

As shown, the PCB may include vias 114 for providing electrical connections between the IC 106 (or the package substrate 108) and the interposer 102. By directly connecting the IC to the interposer through the PCB (e.g., using vias 114), signal impairment (e.g., attenuation) is reduced due to the shortness of the signal channel between the IC 106 and the interposer 102.

As used herein, an interposer generally refers to any material (e.g., a circuit board or a silicon interposer) mounted to the circuit board 104 (e.g., mounted to the bottom of circuit board 104) using connection elements such as a BGA. The interposer may include high-speed capable material such as a high-performance PCB or other materials.

The interposer 102 may be used to mount components such as low-profile connectors for high-speed copper cables, directly soldered cables, optical engines or point-of-load circuitry, as described in more detail herein. The decoupling of the package substrate 108 from the interposer 102 by implementing the package substrate 108 and interposer 102 on reverse sides of the circuit board 104 provides manufacturing simplifications as compared to attaching everything on the package substrate 108. Using the interposer 102 also provides greater surface area for the attachment of additional components without increasing the size of the package substrate 108. Implementing the interposer 102 does not alter (or at least has little effect on) the IC design flow or layout constraints. Moreover, implementation of some functionality on the interposer 102 separates thermal loads into different airflows above and below the circuit board 104.

As shown in FIG. 1, to implement in-package copper (IPC), cables can be coupled to the interposer 102. The interposer 102 provides an approach to implement IPC by decoupling the cable or connector attach area from the IC substrate, relaxing the manufacturability challenges around IPC. With ASIC capacity increasing and the pressure of reducing system power also increasing, there is considerable focus on reducing the IO power on the system. Since higher speed interfaces are used to address the bandwidth capacity challenge, this puts pressure on interfaces to become lower power which directly reduces the achievable distances of cables. One approach to solve this is to draw all the optical IOs closer to the IC (e.g., using CPO) thereby reducing the electrical high-speed channel distances. However, CPO does not solve the full customer specifications to have a mix of optic reaches or even copper cables, so a solution that supports this flexibility is important. IPC is an approach that addresses the primary challenge of having a low-loss high-speed capable electrical channel to keep the IC IO power low, while providing channel reach to enable practical design solutions for interface flexibility. As shown in FIG. 1, to implement IPC, cables are coupled to the interposer 102 on a back side of the circuit board 104. The cables can be soldered directly to the interposer to reduce the launch losses or use high-density cable connectors.

As shown, the interposer 102 may include an interface 130 (e.g., a high-speed interface) for coupling of traces of the interposer to a cable 132 (e.g., an electrical cable). For example, the BGA 112 are implemented on a first surface 170 of the interposer 102, and the interface 130 is implemented on a second surface 172 of the interposer 102. The surfaces 170, 172 are opposite surfaces of the interposer 102. While a single cable is shown in FIG. 1 to facilitate understanding, any number of cables may be attached to interposer 102. The attachment of the cables to the interposer 102 may be implemented via direct soldering of the copper cables or use of low-profile connectors.

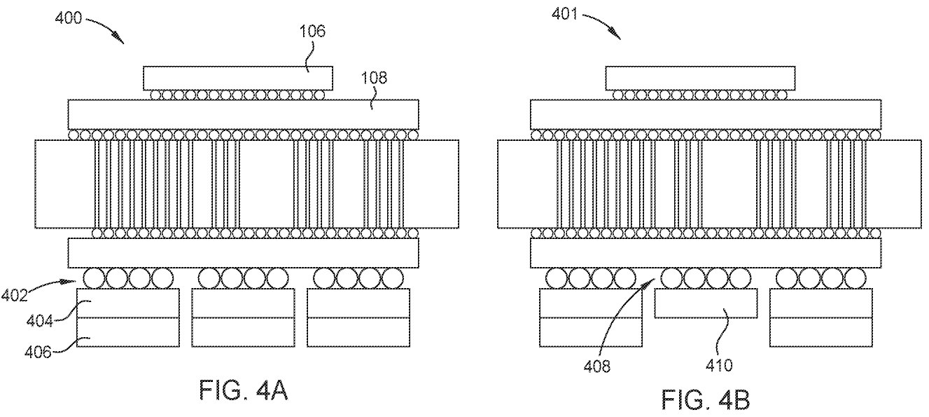

In some embodiments, the interposer 102 includes a power plane or ground plane, such as plane 190, as shown. For example, a power plane that would otherwise be implemented in the circuit board 104 may instead be implemented in the interposer 102, allowing a reduction of the thickness of the circuit board 104. As described in more detail herein with respect to FIG. 4B, a power module may be coupled to the interposer 102 for providing power (e.g., a regulated voltage) to the power plane.

FIG. 2 is a bottom view of the BMI having multiple interfaces coupled to cables, in accordance with an embodiment of the present disclosure. For example, the interposer 102 may include interfaces 202, 204, each facilitating connection to one or more cables, such as cables 206 or cables 208. The cables 206, 208 may facilitate signal communication to other components such as optical engines, other ICs, power modules, or pluggable optical modules, as described in more detail herein.

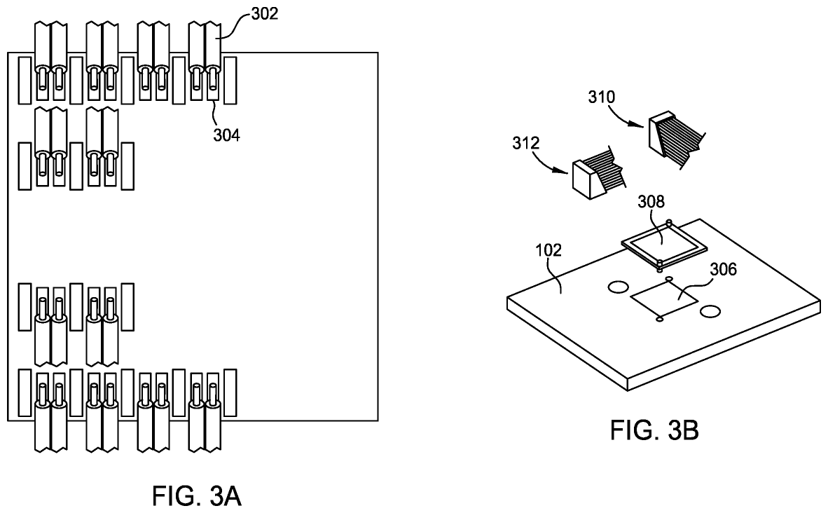

FIG. 3A illustrates cables soldered to solder pads on the interposer 102. In other words, in the example implementation shown in FIG. 3A, the interfaces between the interposer and the cables includes solder pads on which cables may be soldered, as shown. For example, cable 302 may be soldered to solder pad 304, as shown. Some solder pads may be designated for signal (e.g., digital or analog signals) communication, and other may be designated for electrical ground (e.g., reference potential).

FIG. 3B illustrates an interface on interposer 102 implemented using a gold pad array facilitating connection to a socket connector and cable stack. For example, interposer 102 may include a gold pad array 306 that may be coupled to a low-profile socket connector 308. A cable stack 310 or 312 is plugged into the socket connector 308, in some embodiments.

FIGS. 4A and 4B illustrate electrical devices 400, 401 having components coupled to a BMI, in accordance with an embodiment of the present disclosure. By leveraging the BMI approach, additional substrate area below the PCB is made available for coupling of additional components. The additional components may be electrically coupled to the IC 106 without the size of the package substrate 108 being increased that can be expensive and impact yields. For example, as shown, the interposer 102 may be used for coupling of various integrated circuits such as optical engines (e.g., for CPO application), and IC point-of-load (POL) circuitry (e.g., a power module including voltage regulation circuitry). For instance, as shown in FIG. 4A, the interposer 102 may include an interface (e.g., BGA 402) for coupling to a package substrate 404, allowing coupling to an optical engine 406, as shown. The optical engine 406 may be used for conversion between optical signals and electrical signals. Similarly, as shown in FIG. 4B, the interposer 102 may include an interface (e.g., BGA 408) for coupling to POL circuitry 410.

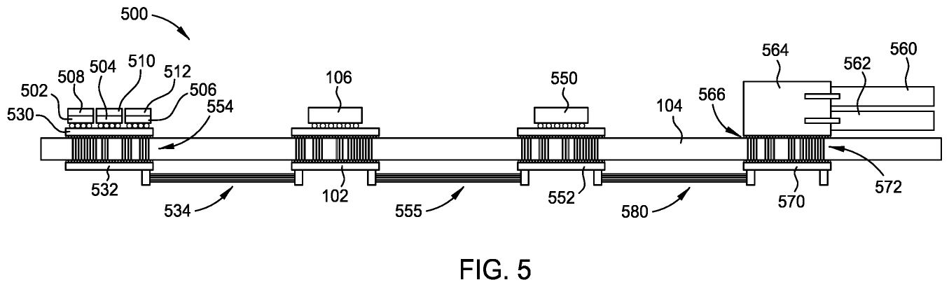

FIG. 5 illustrates an electrical device 500 having multiple BMIs coupled to a circuit board 104, in accordance with an embodiment of the present disclosure. While FIG. 5 shows four BMIs coupled to the circuit board 104 to facilitate understanding of various use cases, the embodiments presented herein can be implemented with any number of BMIs on a circuit board. By using the BMI approach, a low-loss IPC can be used to separate an IC (e.g., IC 106) from an external IO device that also uses a BMI, including such devices such as optical engines 508, 510, 512. In this manner, the separate devices may be implemented with low thermals, improved yields, and manufacturability. As shown, multiple substrates 502, 504, 506 are coupled to the package substrate 530, each of the substrates 502, 504, 506 facilitating an optical engine 508, 510, or 512 as an example. Electrical connection between the IC 106 and the optical engines 508, 510, 512 may be facilitated through interposer 532 (e.g., a BMI), cable 534 and interposer 102, as shown. Vias 554 are used to provide electrical coupling between the package substrate 530 on which the optical engines 508, 510, 512 are disposed and the interposer 532, as shown.

Using a BMI approach to enable low-loss, high-speed copper cable attach provides various advantages such as enabling the usage of low-cost linecard PCB materials and allowing flexibility of placement for various other technologies that may simplify manufacturability or thermal design. For example, as described, embedded optics (e.g., optical engines 508, 510, or 512) may be separated from the IC 106. Moreover, cables between interposers (e.g., interposers 102, 552) may be used to facilitate IC to IC interconnections (e.g., the interconnection between IC 106 and IC 550). Thus, fewer low-loss PCB materials may be used to facilitate connections between ICs.

The BMI approach also enables IC to pluggable module connection. For example, the BMI approach enables connection between an IC (e.g., IC 550) to pluggable modules 560, 562 (either optics or copper cables) through a pluggable connector 564, as shown. For example, the pluggable connector 564 is coupled to the circuit board 104 through a BGA 566 and coupled to interposer 570 (e.g., a BMI) through vias 572. The interposers 552, 570 are electrically coupled using cables 580, as shown.

While the examples provided herein implement signal communication between interposers using cables to facilitate understanding, the communication between the interposers may be by any suitable medium. For example, a medium may be provided to communicate optical signals between interposers as a means of communication. For example, while certain examples provided herein describe electrical cables between interposers, optical cables may also be used to communicate optical signals from one interposer to another.

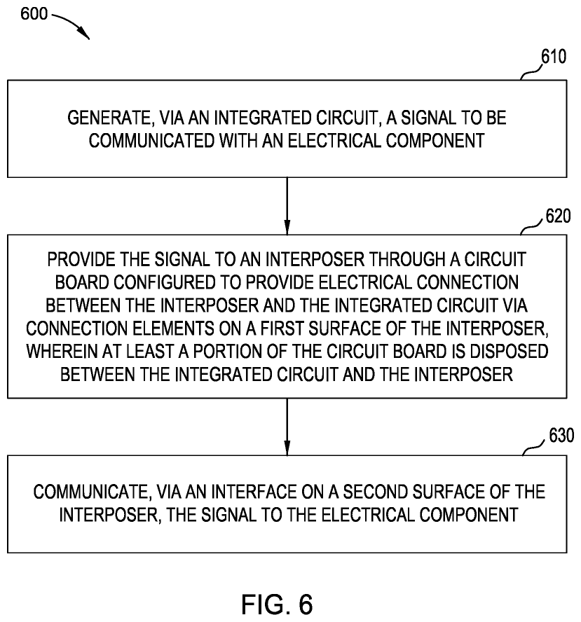

FIG. 6 is a flow diagram illustrating example operations 600 for signal communication using a BMI, in accordance with an embodiment of the present disclosure. The operations 600 may be performed by an electrical device, such as the electrical device 100, 400, 401, and 500.

The operations 600 begin, at block 610, with the electrical device generating (e.g., via IC 106) a signal to be communicated with an electrical component. At block 620, the electrical device provides the signal to an interposer (e.g., interposer 102) through a circuit board (e.g., circuit board 104) configured to provide electrical connection between the interposer and the integrated circuit via connection elements (e.g., BGA 112) on a first surface (e.g., surface 170) of the interposer. At least a portion of the circuit board is disposed between the integrated circuit and the interposer, in some embodiments. At block 630, the electrical device communicates (e.g., via interface 130 on a second surface 172 of the interposer) the signal to the electrical component.

In some embodiments, the circuit board includes a via (e.g., one of vias 114) coupling a connection element (e.g., of BGA 110) of the integrated circuit to the connection element on the first surface of the interposer. In some embodiments, the integrated circuit is disposed on a package substrate (e.g., package substrate 108).

In some implementations, one or more cables (e.g., cable 132) is coupled to the interface on the interposer, the one or more cables being electrically coupled to the integrated circuit through the interposer and the circuit board. In some cases, the interface includes one or more solder pads (e.g., solder pad 304). The one or more cables (e.g., cable 302) may be soldered to the one or more solder pads.

In some embodiments, the interposer includes a ground plane or a power plane (e.g., plane 190). The electrical component may include another integrated circuit coupled to the second side of the interposer, the first and second sides being opposite sides of the interposer. The other integrated circuit may include an optical module (e.g., optical engine 406) or a power module (e.g., POL circuitry 410).

In some embodiments, another interposer (e.g., interposer 532, 552, or 570) is coupled to another portion of the circuit board. In this case, the interface is configured to communicatively couple the interposer and the other interposer. For example, one or more cables (e.g., cables 534, 555, or 580) may be coupled between the interface and the other interposer. In some embodiments, the other portion of the circuit board is disposed between the other interposer and a pluggable connector (e.g., pluggable connector 564), another integrated circuit (e.g., IC 550), or one or more optical modules (e.g., optical engines 508, 510, 512).

In some embodiments, the interface may includes a pad array (e.g., pad array 306. A socket connector (e.g., socket connector 308) may be coupled to the pad array. In some embodiments, a cable stack (e.g., cable stack 310) is coupled to the socket connector.

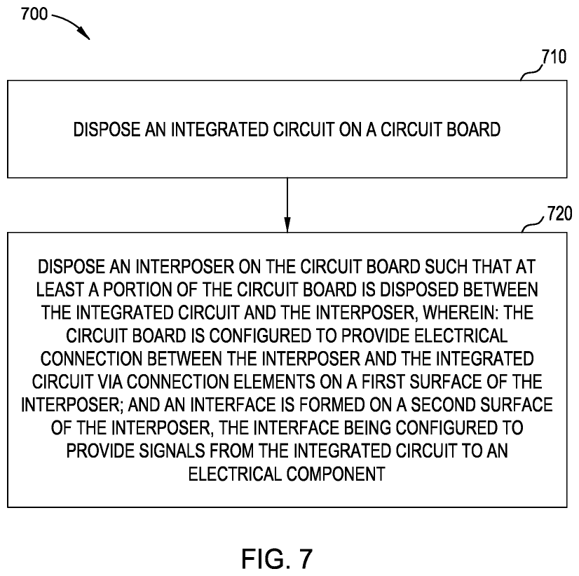

FIG. 7 is a flow diagram illustrating example operations 700 for fabrication, in accordance with an embodiment of the present disclosure. The operations 700 may be performed by a fabrication facility.

The operations 700 begin, at block 710, by disposing an integrated circuit (e.g., IC 106) on a circuit board (e.g., circuit board 104). At block 720, fabrication facility disposes an interposer on the circuit board such that at least a portion of the circuit board is disposed between the integrated circuit and the interposer. In some embodiments, the circuit board is configured to provide electrical connection between the interposer and the integrated circuit via connection elements on a first surface (e.g., surface 170) of the interposer. In some embodiments, an interface (e.g., interface 130) is formed on a second surface (e.g., surface 172) of the interposer, the interface being configured to provide signals from the integrated circuit to an electrical component.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

In view of the foregoing, the scope of the present disclosure is determined by the claims that follow.

We claim:

1. An apparatus comprising:
an integrated circuit;
an interposer;
a circuit board, at least a portion of the circuit board being disposed between the integrated circuit and the interposer, wherein the circuit board is configured to provide electrical connection between the interposer and the integrated circuit via a connection element on a first surface of the interposer; and
an interface on a second surface of the interposer, the interface being configured to provide signals from the integrated circuit to an electrical component.

2. The apparatus of claim 1, wherein the circuit board comprises a via coupling a connection element of the integrated circuit to the connection element on the first surface of the interposer.

3. The apparatus of claim 1, wherein the connection element is a solder connection element.

4. The apparatus of claim 1, wherein the integrated circuit is disposed on a package substrate.

5. The apparatus of claim 1, further comprising one or more cables coupled to the interface on the interposer, the one or more cables being electrically coupled to the integrated circuit through the interposer and the circuit board.

6. The apparatus of claim 5, wherein the interface comprises one or more solder pads, and wherein the one or more cables are soldered to the one or more solder pads.

7. The apparatus of claim 1, wherein the interposer comprises a ground plane or a power plane.

8. The apparatus of claim 1, wherein the electrical component comprises another integrated circuit coupled to the second surface of the interposer, the first surface and the second surface being opposite surfaces of the interposer.

9. The apparatus of claim 8, wherein the other integrated circuit comprises an optical module or a power module.

10. The apparatus of claim 1, wherein the connection element is part of a ball grid array (BGA).

11. The apparatus of claim 1, further comprising another interposer coupled to another portion of the circuit board, wherein the interface is configured to communicatively couple the interposer and the other interposer.

12. The apparatus of claim 11, further comprising one or more cables coupled between the interface and the other interposer.

13. The apparatus of claim 11, further comprising a pluggable module connector, wherein the other portion of the circuit board is disposed between the other interposer and the pluggable module connector.

14. The apparatus of claim 11, further comprising another integrated circuit, wherein the other portion of the circuit board is disposed between the other interposer and the other integrated circuit.

15. The apparatus of claim 11, further comprising one or more optical modules, wherein the other portion of the circuit board is disposed between the other interposer and the one or more optical modules.

16. The apparatus of claim 1, wherein the interface comprises a pad array, the apparatus further comprising a socket connector configured to be coupled to the pad array.

17. The apparatus of claim 16, further comprising a cable stack coupled to the socket connector.

18. The apparatus of claim 1, wherein the interposer comprises a semiconductor interposer.

19. A method comprising:
generating, via an integrated circuit, a signal to be communicated with an electrical component;
providing the signal to an interposer through a circuit board configured to provide electrical connection between the interposer and the integrated circuit via connection elements on a first surface of the interposer, wherein at least a portion of the circuit board is disposed between the integrated circuit and the interposer; and
communicating, via an interface on a second surface of the interposer, the signal to the electrical component.

20. A method comprising:
disposing an integrated circuit on a circuit board; and
disposing an interposer on the circuit board such that at least a portion of the circuit board is disposed between the integrated circuit and the interposer, wherein:
the circuit board is configured to provide electrical connection between the interposer and the integrated circuit via connection elements on a first surface of the interposer; and
an interface is formed on a second surface of the interposer, the interface being configured to provide signals from the integrated circuit to an electrical component.
